(19) United States
(12) Patent Application Publication
(10) Pub. No.: US 2014/0158951 A1
(43) Pub. Date: Jun. 12, 2014

(54) Zn-Si-O-BASED OXIDE SINTERED BODY, METHOD FOR PRODUCING THE SAME, AND TRANSPARENT CONDUCTIVE FILM

(71) Applicants: Yasunori Yamanobe, Tokyo (JP); Kentaro Sogabe, Tokyo (JP); Makoto Ozawa, Tokyo (JP)

(72) Inventors: Yasunori Yamanobe, Tokyo (JP); Kentaro Sogabe, Tokyo (JP); Makoto Ozawa, Tokyo (JP)

(73) Assignee: SUMITOMO METAL MINING CO., LTD., Tokyo (JP)

(21) Appl. No.: 14/237,431

(22) PCT Filed: Jul. 3, 2012
(86) PCT No.: PCT/JP2012/066963

§ 371 Date: Feb. 6, 2014

(30) Foreign Application Priority Data
Sep. 22, 2011 (JP) 2011-207198

(51) Int. Cl. H01B 1/08; C30B 1/02; C23C 14/34; H01J 37/34

(52) U.S. Cl. CPC H01B 1/08; H01J 37/3426; C30B 1/02; C23C 14/3414
USPC 252/519.12; 204/298.13; 117/7; 252/519.1

(57) ABSTRACT

[Object] Provided are: a Zn—Si—O-based oxide sintered body, which suppresses abnormal discharge and so forth when used as a sputtering target, or suppresses a splash phenomenon when used as a tablet for vapor deposition; a method for producing the Zn—Si—O-based oxide sintered body; and the like.

[Solution] The Zn—Si—O-based oxide sintered body contains zinc oxide as a main component and Si, and is characterized in that a Si content is 0.1 to 10 atomic % with an atomic ratio of Si/(Zn+Si), the Si element is contained in a wurtzite-type zinc oxide phase to form a solid solution, and the oxide sintered body does not contain a SiO₂ phase and zinc silicate (Zn₂SiO₄) as a spinel-type composite oxide phase. In producing the sintered body by pressing a granulated powder obtained from a ZnO powder and SiO₂ powder, which are raw material powders, and sintering the compact, the method for producing the sintered body is characterized by including the steps of: raising a temperature in a sintering furnace in a temperature range from 700 to 900° C. at a rate of temperature rise of 5° C./minute or more; and sintering the compact from 900° C. to 1400° C. in the sintering furnace.

### TECHNICAL FIELD

The present invention relates to a Zn—Si—O-based oxide sintered body used as a sputtering target, a tablet for vapor deposition, and the like, and a method for producing the Zn—Si—O-based oxide sintered body. Particularly, the present invention relates to: a Zn—Si—O-based oxide sintered body capable of continuously depositing films for an extended period by suppressing abnormal discharge when used in a sputtering method, or by suppressing a splash phenomenon when used in a vapor deposition method such as ion plating; a method for producing the Zn—Si—O-based oxide sintered body; and a high-transmittance transparent conductive film produced by the film deposition methods.

### BACKGROUND ART

Transparent conductive films having high electrical conductivities and high transmittances in the visible region are used for solar cells, liquid crystal display elements, surface elements for organic electroluminescence, inorganic electroluminescence, etc., electrodes for touch panels, and the like, and are also used as heat ray reflection films for automobile windows or architecture, antistatic films, and for various anti-fogging transparent heaters for freezer showcases and the like.

Here, examples of films known as the transparent conductive films include tin oxide (SnO₂)-based thin films, zinc oxide (ZnO)-based thin films, indium oxide (In₂O₃)-based thin films, and the like.

As the tin oxide-based thin films, those containing antimony as a dopant (ATO) and those containing fluorine as a dopant (FTO) are commonly used. Meanwhile, as the zinc oxide-based thin films, those containing aluminum as a dopant (AZO) and those containing gallium as a dopant (GZO) are commonly used. The transparent conductive films most commonly used in the industrial field are based on indium oxide. Among these, indium oxide films containing tin as a dopant, i.e., In—Sn—O-based films, which are referred to as ITO (Indium tin oxide) films, are widely used especially because low-resistance transparent conductive films are easily obtained.

As a method for producing these transparent conductive films, a sputtering method is often used. The sputtering method is an effective method when a film is deposited from a material having a low vapor pressure or when precise control of the film thickness is required. The method is widely used in the industrial field because the operation is very simple.

Further, in the sputtering method, a sputtering target is used as a raw material of a thin film. This method generally uses a substrate as an anode and the sputtering target as a cathode. An argon plasma is generated by causing a glow discharge between the two under a gas pressure of approximately 10 Pa or below. Argon cations in the plasma collide with the sputtering target serving as the cathode, and constituent particles of the target thus ejected are deposited onto the substrate to deposit a thin film. Meanwhile, the aforementioned transparent conductive films are produced also by using vapor deposition methods such as an ion plating method.

Here, indium oxide-based materials such as ITO described above are widely used in the industrial field. However, indium is a rare metal and expensive, and the materials contain a toxic component such as an indium element, which adversely influences the environment and human. For this reason, there has been a demand for indium-free transparent conductive film materials recently. Next, as the indium-free materials, zinc oxide-based materials such as AZO and GZO, and tin oxide-based materials such as FTO and ATO are known as described above. Particularly, the reserve of the zinc oxide-based materials is sufficient, so that the materials have drawn attention not only as low-cost materials, but also as materials friendly to both the environment and human. Moreover, the zinc oxide-based materials have drawn attention as materials that demonstrate properties comparable to those of ITO.

Nevertheless, it is difficult to stably produce a transparent conductive film having a high transmittance and a low specific resistance comparable to those of ITO, using a zinc oxide-based material in reality. One of the causes is abnormal discharge that occurs during the film deposition. Specifically, when a transparent conductive film is deposited by a sputtering method using a zinc oxide-based material, the abnormal discharge (arcing) occurs frequently, which makes stable film deposition difficult. The cause of the frequent abnormal discharges is that a portion having a high specific resistance (phase having a high resistance value) is locally present in the zinc oxide-based material, and this portion is electrically charged during the film deposition. On the other hand, in a case where a transparent conductive film is deposited by a vapor deposition method such as an ion plating method using a zinc oxide-based material (tablet for vapor deposition) also, a high-specific-resistance portion locally present in the zinc oxide-based material makes uniform sublimation difficult using plasma beams or electron beams, so that a splash phenomenon is likely to occur, in which an evaporation material (tablet for vapor deposition) having a size of approximately several μm to 1000 μm is scattered along with a uniformly evaporated gas, and this evaporation material collides with a deposition film. Moreover, the splash phenomenon causes a pinhole defect or the like in the deposition film. Accordingly, in the film deposition by a vapor deposition method also, it is difficult to stably produce a transparent conductive film having a high transmittance and a low specific resistance.

In order to avoid such problems, Patent Document 1 thus proposes a zinc oxide-based sintered body containing any one or more of Al, Ga, In, Ti, Si, Ge, and Sn as a dopant. Specifically, according to Patent Document 1, zinc oxide and an oxide of an additional element are mixed in advance, and the mixture is calcined to form a spinel-type composite oxide phase such as ZnM₂O₄ or Zn₂MO₄ (M represents an additional element). Then, the calcined powder and a zinc oxide powder not having been calcined are mixed and sintered to thereby prevent formation of a new spinel-type composite oxide phase in the sintering step, and to suppress generation of voids. When such a zinc oxide-based sintered body is used as a sputtering target, it is possible to reduce the abnormal discharge, but it is difficult to completely eliminate the abnormal discharge. In addition, if abnormal discharge occurs in a continuous line for film deposition even once, the products during the film deposition are all defective products, bringing about a problem of adversely influencing the production yield.

Additionally, since zinc oxide-based transparent conductive films are generally inferior in heat resistance and moisture resistance, properties such as transmittance and specific resistance tend to deteriorate in an environment with heat or moisture load, as time elapses. Hence, in order to improve the moisture resistance of a transparent conductive film to be obtained, Patent Document 2 proposes an oxide-based sputtering target containing Ga and Si in predetermined amounts and zinc oxide as a main component. However, in the invention described in Patent Document 2, Si oxide crystal particles are made 200 μm or less to stabilize the discharge, but it is still impossible to eliminate abnormal discharge completely.

Under such a technical background, the present applicant has optimized contents of aluminum and gallium in an oxide sintered body containing zinc oxide as a main component and further aluminum and gallium as additional elements, and also optimally controlled the type and composition of a crystal phase formed during sintering, particularly the composition of a spinel crystal phase. Thus, the applicant has proposed an oxide sintered body for target, from which particles are hardly formed even when films are continuously deposited for an extended period using a sputtering apparatus, and abnormal discharge does not occur even under a high direct current power input (see Patent Document 3).

Moreover, the use of the zinc oxide-based sintered body described in Patent Document 3 enables deposition of a high-quality transparent conductive film having a lower resistance and a higher transmittance than conventional films. Nonetheless, it is still difficult to stably produce a transparent conductive film having a high transmittance comparable to that of ITO.

### CONVENTIONAL ART DOCUMENTS

### Patent Documents

Patent Document 1: Japanese Patent Application Publication No. 2008-63214 (see paragraphs 0022-0032)

Patent Document 2: Japanese Patent No. 4067141 (see claims 1, 2)

Patent Document 3: Japanese Patent No. 4231967 (see paragraph 0013)

### SUMMARY OF THE INVENTION

### Problems to be Solved by the Invention

The present invention has been made in view of such problems as described above. An object of the present invention is to provide: a Zn—Si—O-based oxide sintered body used as a sputtering target or a tablet for vapor deposition; and a method for producing the Zn—Si—O-based oxide sintered body, the Zn—Si—O-based oxide sintered body being capable of stably depositing a transparent conductive film having a high transmittance comparable to that of ITO, and suppressing the above-described abnormal discharge when used as a sputtering target, or suppressing the above-described splash phenomenon when used as a tablet for vapor deposition. Together, to be provided is a transparent conductive film deposited using the oxide sintered body.

### Means for Solving the Problems

Accordingly, the present inventors have earnestly studied to achieve the above objects. As a result, the inventors have found out that the following fact. Specifically, by optimizing a method for producing a Zn—Si—O-based oxide sintered body containing zinc oxide as a main component and as an additional element Si having a high affinity for oxygen, and by controlling an oxide phase of the additional element as a single phase (SiO₂ phase) and a composite spinel crystal phase formed during sintering, particularly deposition of the oxide phases near crystal grain boundaries in the sintered body, a Zn—Si—O-based oxide sintered body is obtained, which is usable as a sputtering target capable of stably depositing films even under a high direct current power input and suppressing occurrences of abnormal discharge and particles even when films are continuously deposited for an extended period using a sputtering apparatus, and further which is usable as a tablet for vapor deposition suppressing the above-described splash phenomenon even when films are continuously deposited for an extended period with a vapor deposition apparatus for ion plating or the like. Moreover, the inventors have found out that a transparent conductive film obtained using the resulting Zn—Si—O-based oxide sintered body as a sputtering target or a tablet for vapor deposition is excellent in transmittance and useful as an electrode for displays, touch panels, and solar cells, and so forth.

Specifically, a Zn—Si—O-based oxide sintered body according to the present invention is a Zn—Si—O-based oxide sintered body containing zinc oxide as a main component and Si, characterized in that

a Si content is 0.1 to 10 atomic % with an atomic ratio of Si/(Zn+Si),

the Si element is contained in a wurtzite-type zinc oxide phase to form a solid solution, and

the oxide sintered body does not contain a SiO₂ phase and zinc silicate (Zn₂SiO₄) as a spinel-type composite oxide phase.

Next, a method for producing a Zn—Si—O-based oxide sintered body according to the present invention is a method for producing a Zn—Si—O-based oxide sintered body, which has a Si content of 0.1 to 10 atomic % with an atomic ratio of Si/(Zn+Si), the Si element being contained in a wurtzite-type zinc oxide phase to form a solid solution, and which does not contain a SiO₂ phase and zinc silicate (Zn₂SiO₄) as a spinel-type composite oxide phase. The method is characterized as follows. Specifically, the method comprises:

a first step of drying a slurry obtained by mixing a ZnO powder and a SiO₂ powder with pure water, an organic binder, and a dispersing agent, followed by granulation;

a second step of pressing the obtained granulated powder to obtain a compact; and

a third step of sintering the obtained compact to obtain the sintered body, and

the third step to obtain the sintered body includes the steps of:
raising a temperature in a sintering furnace in a temperature range from 700 to 900° C. at a rate of temperature rise of 5° C./minute or more; and
sintering the compact from 900° C. to 1400° C. in the sintering furnace.

Further, a transparent conductive film according to the present invention is characterized by being deposited by a sputtering method using a sputtering target obtained by processing the Zn—Si—O-based oxide sintered body, or a vapor deposition method using a tablet for vapor deposition obtained by processing the Zn—Si—O-based oxide sintered body.

### Advantageous Effects of Invention

The Zn—Si—O-based oxide sintered body according to the present invention is characterized in that

the Si content is 0.1 to 10 atomic % with an atomic ratio of Si/(Zn+Si),

the Si element is contained in a wurtzite-type zinc oxide phase to form a solid solution, and

the oxide sintered body does not contain a SiO₂ phase and zinc silicate (Zn₂SiO₄) as a spinel-type composite oxide phase.

The use of a sputtering target obtained by processing the Zn—Si—O-based oxide sintered body does not cause abnormal discharge (arcing) which have conventionally been a problem of targets such as AZO and GZO, even when direct-current sputtering is performed by increasing a direct current power density to increase the production efficiency. Further, even when the sputtering target is used for continuous film deposition for an extended period, particles are also hardly formed due to peeling off of a film adhering to the surface of a target or the like. Thus, the sputtering target has an effect of enabling film deposition in large quantities with high yield with few defective products.

Moreover, the use of a tablet for vapor deposition made of the Zn—Si—O-based oxide sintered body of the present invention does not cause the above-described splash phenomenon, even when films are continuously deposited for an extended period with a vapor deposition apparatus for ion plating or the like. Thus, the tablet for vapor deposition has an effect of enabling film deposition in large quantities with high yield with few defective products as in the case of using the sputtering target.

Further, since containing Si that is highly likely to bond to oxygen, the transparent conductive film deposited using a sputtering target or a tablet for vapor deposition obtained from the Zn—Si—O-based oxide sintered body of the present invention is excellent in transmittance. Accordingly, the transparent conductive film has an effect of being suitably usable as a transparent electrode for flat panel displays, touch panels, light emitting devices, solar cells, and the like.

### BEST MODES FOR PRACTICING THE INVENTION

Embodiments of the present invention are described below in detail.

### 1. Zn—Si—O-Based Oxide Sintered Body

A Zn—Si—O-based oxide sintered body according to the present invention is characterized in that a Si content is 0.1 to 10 atomic % with an atomic ratio of Si/(Zn+Si), the Si element is contained in a wurtzite-type zinc oxide phase to form a solid solution, and the oxide sintered body does not contain a SiO₂ phase and zinc silicate (Zn₂SiO₄) as a spinel-type composite oxide phase. The oxide sintered body is used as a sputtering target or a tablet for vapor deposition by ion plating or the like. Moreover, the oxide sintered body may comprise at least one additional element selected from Mg, Al, Ti, Ga, In, and Sn in order to decrease the specific resistance. Note that a content of the additional element(s) is desirably 0.01 to 10 atomic % with an atomic ratio of M/(Zn+Si+M), where M represents all components of the additional elements.

In the Zn—Si—O-based oxide sintered body according to the present invention, if the Si content exceeds 10 atomic % with the atomic ratio of Si/(Zn+Si), oxide phases of spinel-type or the like are formed in the Zn—Si—O-based oxide sintered body. Since these oxide phases are high-resistance or insulating substances, the oxide phases induce abnormal discharge during film deposition by sputtering described above, and induce a splash phenomenon during vapor evaporation by ion plating or the like described above. Particularly, SiO₂ tends to deposit on crystal grain boundaries in the Zn—Si—O-based oxide sintered body. If such a deposition cannot be suppressed, it is impossible to completely eliminate the abnormal discharge and splash phenomenon described above. In addition, if the content of the additional element(s) exceeds 10 atomic % with the atomic ratio of M/(Zn+Si+M), this induces abnormal discharge during film deposition by sputtering described above, and induces a splash phenomenon during vapor evaporation by ion plating or the like described above.

On the other hand, if the Si content is less than 0.1 atomic % with the atomic ratio of Si/(Zn+Si), there are few free electron carriers, which are to be described later, and the conductivity becomes insufficient regardless of the formed compound phase. Hence, abnormal discharge occurs during film deposition. Moreover, if the content of the additional element(s) is less than 0.01 atomic % with the atomic ratio of M/(Zn+Si+M), this makes it difficult to demonstrate an effect of decreasing the specific resistance.

Further, in the Zn—Si—O-based oxide sintered body according to the present invention, the wurtzite-type zinc oxide phase in the oxide sintered body refers to a phase having a hexagonal wurtzite structure, and includes phases having a non-stoichiometric composition such as oxygen deficit or zinc deficit compositions. The zinc oxide phase in a state of such a non-stoichiometric composition generates free electrons and improves the conductivity. Hence, the zinc oxide phase has effects of suppressing abnormal discharge during film deposition by sputtering and a splash phenomenon during vapor evaporation by ion plating or the like. Moreover, the wurtzite-type zinc oxide phase, as described above, contains the Si element to form a solid solution, and contains the additional element(s) selected from Mg, Al, Ti, Ga, In, and Sn, which are contained as necessary, to form a solid solution. As these elements are contained at zinc sites (wurtzite-type zinc oxide phase) to form a solid solution, free electron carriers are generated, improving the conductivity. This contributes to the suppression of abnormal discharge during film deposition by sputtering and a splash phenomenon during vapor evaporation by ion plating or the like.

### 2. Method for Producing Zn—Si—O-Based Oxide Sintered Body

A method for producing a Zn—Si—O-based oxide sintered body according to the present invention comprises:

a “first step” of drying a slurry obtained by mixing raw material powders with pure water, an organic binder, and a dispersing agent, followed by granulation;

a “second step” of pressing the obtained granulated powder to obtain a compact; and

a “third step” of sintering the obtained compact to obtain the sintered body.

### [First Step]

The “granulated powder” obtained in the first step can be produced by any of the two methods.

### (First Method)

The raw material powders used are a ZnO powder, a SiO₂ powder, and Mg, Al, Ti, Ga, In, and Sn oxide powders, which are added as necessary. The raw material powders are mixed with pure water, an organic binder, and a dispersing agent. The mixing is performed with a concentration of the raw material powders being 50 to 80 wt %, preferably 60 wt %. Then, the mixture is ground in a wet method until the average particle diameter becomes 0.5 μm or less. In this event, particularly, the average particle diameters of both of the ZnO powder and the SiO₂ powder used as the raw materials are made 1.0 μm or less, and the average particle diameter of the mixture powder is reduced to 0.5 μm or less. Further, in the grinding in a wet method, a “ball mill” using balls having a particle diameter (ball diameter) of more than 2.0 mm is not suitable for breaking down into particles having a particle diameter 1.0 μm or less. Accordingly, it is preferable to use a “bead mill” using ones having a particle diameter (bead diameter) of 2.0 mm or less. This production method reliably removes aggregates of the ZnO powder, the SiO₂ powder, and the like, making it possible to prevent aggregates of Si-based oxides, which are otherwise formed in a later step. After the grinding, a slurry obtained therefrom by stirring for mixing for 30 minutes or more is dried and granulated to obtain a “granulated powder.”

### (Second Method)

The raw material powders used are: a ZnO powder, a SiO₂ powder, and Mg, Al, Ti, Ga, In, and Sn oxide powders, which are added as necessary; and a calcined powder obtained by mixing and calcining a ZnO powder, a SiO₂ powder, and Mg, Al, Ti, Ga, In, and Sn oxide powders, which are added as necessary. When the calcined powder is to be produced, the calcining is performed from 900° C. to 1400° C., preferably 900° C. to 1200° C., and it is important to raise a temperature of the powders (in a calcining furnace) in a temperature range from 700 to 900° C., where an intermediate compound phase represented by a spinel phase such as ZnM₂O₄ or Zn₂MO₄ (M represents an additional element) is most likely to be formed, at a rate of temperature rise of 5° C./minute or more.

Next, the raw material powders of the calcined powder and the ZnO powder, the SiO₂ powder, and the Mg, Al, Ti, Ga, In, and Sn oxide powders, which are added as necessary, are mixed with pure water, an organic binder, and a dispersing agent. The mixing is performed with a concentration of the raw material powders being 50 to 80 wt %, preferably 70 wt %. Then, a slurry obtained therefrom by stirring for mixing for 10 hours or more is dried and granulated to obtain a “granulated powder.” In the second method also, particularly, the average particle diameters of both of the ZnO powder and the SiO₂ powder used as the raw materials are made 1.0 μm or less to reliably remove aggregates of the ZnO powder, the SiO₂ powder, and the like, making it possible to prevent aggregates of Si-based oxides, which are otherwise formed in a later step.

### [Second Step]

In a case where a sputtering target is to be formed, the “granulated powder” is used and pressed under a pressure of 98 MPa (1.0 ton/cm²) or more to obtain a compact. If the pressing is performed at less than 98 MPa, voids present among the particles are difficult to remove, so that the density of the sintered body decreases. Moreover, since the strength of the compact decreases, the compact is difficult to produce stably. Here, when the pressing is performed, cold isostatic pressing (CIP) is desirably employed, with which a high pressure can be achieved.

On the other hand, in a case where a tablet for vapor deposition is to be formed, the “granulated powder” is pressed by, for example, mechanical pressing in which the granulated powder is pressed in a die, or the like, to obtain a compact. In the step to obtain the compact, the “granulated powder” is preferably pressed under a pressure of 49 MPa (0.5 ton/cm²) to 147 MPa (1.5 ton/cm²), because a sintered body having a desired relative density can be obtained easily. Note that the compact is preferably chamfered by using a die having chamfered edge portions for the pressing. This is because chipping and the like can be prevented during handling of the compact and a sintered body obtained by sintering the compact.

### [Third Step]

The compact obtained in the second step is sintered at normal pressure to obtain the Zn—Si—O-based oxide sintered body. The sintering is performed at a sintering temperature from 900 to 1400° C., preferably 1100° C. to 1300° C. If the sintering temperature is lower than 900° C., necessary contraction due to sintering is not achieved, which results in a sintered body having a low mechanical strength. Moreover, since the contraction due to sintering proceeds insufficiently, the density and size of the obtained sintered body vary a lot. In a range from 900° C. and higher, the sintering proceeds and Si atoms are uniformly present inside crystal particles in the sintered body. Nevertheless, if a thermal energy at a temperature higher than necessary is applied, a region where the concentration of Si added as impurities is high is formed inside the crystal particles adjacent to grain boundaries, which deteriorates the conductivity as a sintered body. The present inventors have confirmed that this phenomenon starts to occur at temperatures exceeding 1400° C. Further, the sintering temperature exceeding 1400° C. is not preferable because zinc oxide (ZnO) is vaporized actively, so that the composition deviates from the predetermined zinc oxide composition.

In addition, it is important that the temperature of the compact (in a sintering furnace) be raised in the temperature range from 700 to 900° C., where an intermediate compound phase represented by a spinel phase such as ZnM₂O₄ or Zn₂MO₄ (M represents an additional element) is most likely to be formed, at the rate of temperature rise of 5° C./minute or more. The present inventors have confirmed that raising the temperature at this rate of temperature rise suppresses the formation of an intermediate compound phase, and that raising the temperature in a temperature range other than 700 to 900° C. at a rate of 3° C./minute or less promotes the diffusion of the Si element to form a solid solution. Moreover, producing the sintered body by these sintering programs makes it possible to suppress the deposition of Si-based oxides and the formation of an intermediate compound phase including a spinel phase.

The obtained sintered body is, as necessary, processed to predetermined shape and dimensions. When used as a sputtering target, the sintered body is bonded to a predetermined backing plate.

### 3. Transparent Conductive Film and Method for Producing the Same

A transparent conductive film of the present invention is deposited on a substrate such as a glass in a film deposition system by a sputtering method using the sputtering target or by a vapor deposition method such as ion plating using the tablet for vapor deposition. The composition of the obtained transparent conductive film reflects the composition of the Zn—Si—O-based oxide sintered body according to the present invention because the oxide sintered body is used as the raw material of the transparent conductive film. Moreover, the transparent conductive film obtained by the present invention is preferably formed of a crystal phase, substantially a wurtzite-type zinc oxide phase, and all the Si elements are contained in the wurtzite-type zinc oxide phase.

Further, the c-axis of the obtained wurtzite-type zinc oxide phase is oriented in a direction perpendicular to the substrate such as a glass. Furthermore, the better the crystallinity (i.e., the larger the crystal particles), the higher the mobility of electron carriers, leading to an excellent conductivity. In addition, the mobility of electron carriers is also increased by increasing the film thickness because the crystallinity is improved.

In the present invention, the transparent conductive film made of zinc oxide containing Si and the additional element(s) added as necessary can be deposited on the substrate by using the sputtering target or the tablet for vapor deposition obtained from the Zn—Si—O-based oxide sintered body, and employing specific film deposition conditions such as substrate temperature and pressure.

The composition of the transparent conductive film obtained by sputtering or a vapor deposition method such as an ion plating method using the Zn—Si—O-based oxide sintered body according to the present invention is the same as the composition of the oxide sintered body as described above. Regarding the composition, if amounts of Si and the additional element(s) added as necessary are too large, not all of them are contained in the zinc oxide phase into a solid solution phase, and Si oxide phases deposit, deteriorating the crystallinity of the thin film. As a result, the conductivity significantly deteriorates due to the decreased mobility of electron carriers. In this case, a film deposition by heating the substrate can improve the solid solubility of Si and the additional element(s) added as necessary. However, the film deposition at high temperature requires dedicated film deposition conditions; in addition, in order to obtain the transparent conductive film having a high conductivity under various conditions for depositing films in large quantities including film deposition at room temperature, the contents of Si and the additional element(s) added as necessary have to be within the above-described ranges. Specifically, the Si content has to be controlled to 0.1 to 10 atomic % with the atomic ratio of Si/(Zn+Si), whereas the content of the additional element (M) selected from Mg, Al, Ti, Ga, In, and Sn (a total amount in a case where multiple elements are used) is preferably controlled to 0.01 to 10 atomic % with the atomic ratio of M/(Zn+Si+M).

Next, the substrate used for the film deposition is not particularly limited by its material such as glass, resin, metal, and ceramic. Although the substrate may be transparent or non-transparent, a transparent substrate is preferable in a case where the substrate is used to deposit a film of a transparent electrode. Moreover, in the case where the substrate is made of a resin, the resin can be used in various shapes such as plate or film. For example, even a resin having a low melting point of 150° C. or lower can also be used. Nevertheless, in this case, it is desirable to deposit a film without heating.

The transparent conductive film obtained from the Zn—Si—O-based oxide sintered body containing Si and the additional element(s) added as necessary is an N-type semiconductor conductive crystalline film containing zinc oxide as a main component, in which zinc ion sites are substituted with ions of the element(s) contained as a dopant. While silicon (Si) ions are positive quadrivalent, substituting a positive divalent zinc ion site with a trivalent or higher valent element generates free electron carriers in the film, leading to an excellent conductivity.

Next, in order to produce the transparent conductive film of the present invention by a sputtering method using the sputtering target, it is preferable to employ direct-current sputtering using an inert gas such as argon as a sputtering gas. For example, after evacuation to 5×10⁻⁵ Pa or below, a pure Ar gas is introduced to set the gas pressure to 0.1 to 1 Pa, particularly 0.2 to 0.8 Pa. A direct current power density (direct current power/target area) of 0.55 to 5.0 W/cm² is applied to generate a direct-current plasma. Thus, pre-sputtering can be performed. After the pre-sputtering is performed for 5 to 30 minutes, sputtering is preferably performed with the position of the substrate being adjusted if necessary. In a case where the sputtering target obtained from the Zn—Si—O-based oxide sintered body according to the present invention is used, this brings about an advantage that stable high-speed film deposition is possible without abnormal discharge even if a high direct current power is inputted.

Moreover, in a case where the tablet for vapor deposition (also called a pellet or a target) prepared from the Zn—Si—O-based oxide sintered body according to the present invention is used also, it is possible to deposit a similar transparent conductive film. For example, in an ion plating method, when the tablet for vapor deposition as an evaporation source is irradiated with heat attributable to electron beams or an arc discharge, or the like, the irradiated portion is locally heated, particles are evaporated and deposited onto the substrate. In this event, the evaporated particles are ionized by the electron beams or arc discharge. Although such an ionization method includes various methods, high-density plasma-assist evaporation (HDPE method) using a plasma generator (plasma gun) is suitable for depositing a high-quality transparent conductive film. This method utilizes an arc discharge using a plasma gun, and the arc discharge is maintained between a cathode inside the plasma gun and a crucible (anode) of an evaporation source. Electrons emitted from the cathode are introduced into the crucible by magnetic field deflection, concentrated and radiated to a local area of the tablet for vapor deposition put in the crucible. Particles are evaporated from the area locally heated by the electron beams and deposited onto the substrate. The evaporated particles thus vaporized and an O₂ gas introduced as a reactive gas are ionized and activated in this plasma, so that a high-quality transparent conductive film can be deposited.

### EXAMPLES

Hereinafter, Examples of the present invention are described specifically together with Comparative Examples. However, the technical configuration of the present invention is not limited by Examples below.

### Example 1

### Preparation of Oxide Sintered Body

As raw material powders, a ZnO powder and a SiO₂ powder each having an average particle diameter of 1.0 μm or less were blended with each other with the atomic ratio of Si/(Zn+Si) being 3.0 atomic %, and mixed with pure water, an organic binder, and a dispersing agent. The mixing was performed with a concentration of the raw material powders being 60 wt %, and a slurry was prepared in a mixing tank.

Next, the slurry was ground in a wet method using a bead mill apparatus (manufactured by Ashizawa Finetech Ltd., Model: LMZ) into which hard ZrO₂ balls having a particle diameter of 0.5 mm were introduced, until the average particle diameter of the raw material powders became 0.5 μm or less. Then, a slurry obtained therefrom by stirring for mixing for 30 minutes or more was spray dried by using a spray dryer apparatus (manufactured by OHKAWARA KAKOHKI CO., LTD., Model: ODL-20) to obtain a “granulated powder.” Note that a laser diffraction particle size distribution analyzer (manufactured by Shimadzu Corporation, SALD-2200) was used for measuring the average particle diameter of the raw material powders.

Next, the obtained “granulated powder” was pressed by applying a pressure of 294 MPa (3 ton/cm²) thereto with a cold isostatic press. A compact of approximately 200 mmφ thus obtained was sintered for 20 hours in air in an atmospheric-pressure sintering furnace with the highest sintering temperature of 1300° C. Thus, an oxide sintered body of Example 1 was obtained. In this event, the rate of temperature rise was of 5° C./minute in a temperature range from 700 to 900° C., and 3° C./minute in a temperature range other than 700 to 900° C.

At this point, end parts of the obtained oxide sintered body were ground, and a phase formed was identified by powder X-ray diffraction measurement using CuKα radiation. As a result, only a peak of a ZnO phase having a hexagonal wurtzite structure was detected, and peaks originating from a SiO₂ phase as a single phase and a spinel-type composite oxide phase of zinc silicate (Zn₂SiO₄) were not detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, the electron diffraction also confirmed that the oxide sintered body had no SiO₂ phase present as a single phase in the matrix phase of the wurtzite-type structure.

### Preparation of Transparent Conductive Film

The obtained oxide sintered body of Example 1 was processed into a diameter of 152.4 mm (6 inches) and a thickness of 5 mm, and bonded using metal indium to a backing plate made of oxygen-free copper. Thus, a sputtering target of Example 1 was obtained.

Next, using the obtained sputtering target of Example 1, a film was deposited by direct-current sputtering. The sputtering target was mounted on a cathode for a non-magnetic target of a DC magnetron sputtering apparatus (manufactured by Tokki Corporation, Ltd., SPF-530K).

On the other hand, as a substrate for film deposition, an alkali-free glass substrate (Corning #7059, a thickness t of 1.1 mm) was used. The distance between the target and the substrate was set to 60 mm.

Then, after evacuation to 5×10⁻⁵ Pa or below, a pure Ar gas was introduced to set the gas pressure to 0.3 Pa. A direct current power of 200 W was applied to generate a direct-current plasma, and pre-sputtering was performed.

After sufficient pre-sputtering, the substrate was placed, while standing still, just above the center (non-eroded portion) of the sputtering target and sputtering was performed without heating. Thus, a transparent conductive film having a thickness of 200 nm was deposited.

As a result, no cracks were formed in the sputtering target, and no abnormal discharge or the like occurred within 10 minutes from the initial stage of the film deposition, either.

Moreover, the transmittance of the obtained film was measured with a spectrophotometer (manufactured by Hitachi, Ltd.). The transmittance including that of the substrate was 87% in the visible region (400 nm to 800 nm), and the transmittance including that of the substrate was 85% in the near-infrared region (800 nm to 1200 nm). Here, the transmittance of the film itself was calculated by [(the transmittance including that of the substrate)/(the transmittance of only the substrate)]×100(%). The transparent conductive film of Example 1 had a transmittance of 89% in the visible region and 92% in the near-infrared region.

Further, the specific resistance of the surface of the obtained film was measured using a four-point probe method with a resistivity meter Loresta-EP (manufactured by Mitsubishi Chemical Analytech Co., Ltd., Model: MCP-T360). The specific resistance value was 8.5×10⁻⁴ Ω·cm.

Accordingly, it has been found that the transparent conductive film of Example 1 is excellent in transmittance not only in the visible region but also in the near-infrared region, and is useful not only for application to devices such as displays, which require visible light transmission, but also for application to solar cells, which require a high transmittance in the near-infrared region.

Here, “Table 1-1” to “Table 1-3” collectively show constituent components of oxide sintered bodies of all Examples, production conditions, the presence or absence of fractures during the production step, the application of the sintered bodies, and so on. As the analysis result of the sintered bodies described above, “Table 2-1” and “Table 2-2” collectively show the state during the film deposition (note that the column of “Abnormal discharge etc. during film deposition” shows the presence or absence of abnormal discharge and particles formed when a film was deposited by sputtering, or the presence or absence of a splash phenomenon when a film was deposited by ion plating), properties of the transparent conductive films, and so on.

### Examples 2, 3, Comparative Examples 1, 2

Oxide sintered bodies were obtained under the same conditions as in Example 1, except that the sintering temperature was 1400° C. (Example 2), 900° C. (Example 3), 1500° C. (Comparative Example 1), and 800° C. (Comparative Example 2).

The obtained oxide sintered bodies were subjected to powder X-ray diffraction measurement in the same method as in Example 1. As a result, only a peak of a ZnO phase having a hexagonal wurtzite structure was detected in all the sintered bodies, and peaks originating from a SiO₂ phase as a single phase and a spinel-type composite oxide phase of zinc silicate (Zn₂SiO₄) were not detected.

Further, end parts of the obtained oxide sintered bodies were cut into thin pieces by FIB processing, which were subsequently observed with a transmission electron microscope (TEM) equipped with an energy dispersive X-ray fluorescence spectrometer (EDX). As a result, the electron diffraction also confirmed that the oxide sintered bodies obtained in Examples 2, 3 and Comparative Example 2 had no SiO₂ phase present as a single phase in the matrix phase of the wurtzite-type structure. However, in Comparative Example 1, a region having a high Si concentration was formed inside the crystal particles adjacent to grain boundaries and a SiO₂ phase was present possibly because the sintering temperature was too high.

Next, the obtained oxide sintered bodies were each processed into a diameter of 152.4 mm (6 inches) and a thickness of 5 mm. Thus, sputtering targets were obtained.

After mounted on a sputtering apparatus (manufactured by Tokki Corporation, Ltd., SPF-530K), these sputtering targets were used for film deposition by the sputtering method under the same conditions as in Example 1. Then, the states of the targets were observed. As a result, in both Examples 2 and 3, no cracks were formed, and no abnormal discharge or the like occurred within 10 minutes from the initial stage of the film deposition, either. On the other hand, in Comparative Examples 1 and 2, abnormal discharge occurred 20 times to 30 times within 10 minutes. The presence of the SiO₂ phase inferior in conductivity in Comparative Example 1 and cracks formed due to low strength of the sintered body attributable to the insufficient sintering in Comparative Example 2 presumably contributed to the abnormal discharges. Moreover, in Comparative Example 1, since the crystal particles were coarsened, the strength of the sintered body was so low that 4 targets among 20 targets were fractured during the processing. In addition, since the sintering temperature was low in Comparative Example 2, the sintering did not proceed, and 12 targets among 20 targets were fractured during the processing. The oxide sintered bodies of Comparative Examples 1 and 2 cannot be used in the process of depositing films in large quantities, which requires high productivity.

Next, the transmittance and the specific resistance value of the obtained film itself were measured and calculated in the same method as in Example 1. As a result, the transmittance in the visible region was 89% (Example 2), 88% (Example 3), 77% (Comparative Example 1), and 81% (Comparative Example 2), and the transmittance in the near-infrared region was 93% (Example 2), 92% (Example 3), 79% (Comparative Example 1), and 81% (Comparative Example 2).

Moreover, the specific resistance value was 8.6×10⁻⁴ Ω·cm (Example 2), 9.0×10⁻⁴ Ω·cm (Example 3), 8.5×10⁻⁴ Ω·cm (Comparative Example 1), and 8.8×10⁻⁴ Ω·cm (Comparative Example 2).

It is thought that the transmittance of the transparent conductive films obtained in Comparative Examples 1 and 2 was deteriorated due to the influence of the abnormal discharge. It has been found that such transparent conductive films cannot be used as a transparent electrode film, which requires a high transmittance.

Note that, as to Comparative Examples also, “Table 3-1” to “Table 3-3” collectively show constituent components of oxide sintered bodies of all Comparative Examples, production conditions, the presence or absence of fractures during the production step, the application of the sintered bodies, and so on. As the analysis result of the sintered bodies described above, “Table 4-1” and “Table 4-2” collectively show the state during the film deposition (note that the column of “Abnormal discharge etc. during film deposition” shows the presence or absence of abnormal discharge and particles formed when a film was deposited by sputtering, or the presence or absence of a splash phenomenon when a film was deposited by ion plating), properties of the transparent conductive films, and so on.

### Examples 4, 5, Comparative Examples 3, 4

Oxide sintered bodies were obtained by using a ZnO powder and a SiO₂ powder each having an average particle diameter of 1.0 μm or less as raw material powders under the same conditions as in Example 1, except that the atomic ratio of Si/(Zn+Si) was 0 atomic % (Comparative Example 3), 0.1 atomic % (Example 4), 10 atomic % (Example 5), and 15 atomic % (Comparative Example 4).

The obtained oxide sintered bodies were subjected to powder X-ray diffraction measurement in the same method as in Example 1. As a result, only a peak of a ZnO phase having a hexagonal wurtzite structure was detected in the sintered bodies of Examples 4, 5 and Comparative Example 3, peaks originating from a SiO₂ phase as a single phase and a spinel-type composite oxide phase of zinc silicate (Zn₂SiO₄) were not detected. On the other hand, in the sintered body of Comparative Example 4, a peak originating from a spinel-type composite oxide phase of zinc silicate (Zn₂SiO₄) was observed in addition to that of the ZnO phase.

Further, end parts of the obtained oxide sintered bodies were cut into thin pieces by FIB processing, which were subsequently observed with a transmission electron microscope (TEM) equipped with an energy dispersive X-ray fluorescence spectrometer (EDX). As a result, the electron diffraction also confirmed that the oxide sintered bodies obtained in Examples 4, 5 and Comparative Example 3 had no SiO₂ phase present as a single phase in the matrix phase of the wurtzite-type structure. However, in Comparative Example 4, a SiO₂ phase not contained into a solid solution phase was present possibly because the concentration of Si added as impurities was high.

Next, the obtained oxide sintered bodies were each processed into a diameter of 152.4 mm (6 inches) and a thickness of 5 mm. Thus, sputtering targets were obtained.

After mounted on a sputtering apparatus (manufactured by Tokki Corporation, Ltd., SPF-530K), these sputtering targets were used for film deposition by the sputtering method under the same conditions as in Example 1. Then, the states of the targets were observed. As a result, in both Examples 4 and 5, no cracks were formed, and no abnormal discharge or the like occurred within 10 minutes from the initial stage of the film deposition, either. On the other hand, abnormal discharge occurred 20 times to 30 times in Comparative Example 3 and 100 times to 120 times in Comparative Example 4 within 10 minutes. The oxide sintered bodies of Comparative Examples 3 and 4 cannot be used in the process of depositing films in large quantities, which requires high productivity.

Next, the transmittance and the specific resistance value of the obtained film itself were measured and calculated in the same method as in Example 1. As a result, the transmittance in the visible region was 89% (Comparative Example 3), 88% (Example 4), 90% (Example 5), and 78% (Comparative Example 4), and the transmittance in the near-infrared region was 90% (Comparative Example 3), 94% (Example 4), 89% (Example 5), and 76% (Comparative Example 4).

Moreover, the specific resistance value was 7.8×10⁻² Ω·cm (Comparative Example 3), 9.0×10⁻¹ Ω·cm (Example 4), 8.1×10⁻¹ Ω·cm (Example 5), and 8.2×10⁻⁴ Ω·cm (Comparative Example 4).

It is thought that the transmittance of the transparent conductive films obtained in Comparative Examples 3 and 4 was deteriorated due to the influence of the abnormal discharge. It has been found that such transparent conductive films cannot be used as a transparent electrode film, which requires a high transmittance.

### Examples 6 to 12, 7-2, 9-2, 12-2

Oxide sintered bodies were obtained under the same conditions as in Example 1, except that a ZnO powder, a SiO₂ powder, and an oxide powder of a third metal element as an additional element each having an average particle diameter of 1.0 μm or less were used as raw material powders under the following conditions: the atomic ratio of Si/(Zn+Si) was 3.0 atomic %; the third additional element was Mg (Example 6), Al (Example 7), Ti (Example 8), Ga (Example 9), In (Example 10), Sn (Example 11), and Al+Ga (Example 12) under a condition of the atomic ratio of M/(Zn+Si+M) being 2.0 atomic %, where M represents the third metal element; furthermore, the third additional element was Al (Example 7-2), Ga (Example 9-2), and Al+Ga (Example 12-2) under a condition of the atomic ratio of M/(Zn+Si+M) being 10 atomic %.

The obtained oxide sintered bodies were subjected to powder X-ray diffraction measurement in the same method as in Example 1. As a result, only a peak of a ZnO phase having a hexagonal wurtzite structure was detected in all the sintered bodies, and peaks originating from a SiO₂ phase as a single phase and a spinel-type composite oxide phase of zinc silicate (Zn₂SiO₄) were not detected.

Further, end parts of the obtained oxide sintered bodies were cut into thin pieces by FIB processing, which were subsequently observed with a transmission electron microscope (TEM) equipped with an energy dispersive X-ray fluorescence spectrometer (EDX). As a result, the electron diffraction also confirmed that the obtained oxide sintered bodies had no SiO₂ phase present as a single phase in the matrix phase of the wurtzite-type structure.

Next, the obtained oxide sintered bodies were each processed into a diameter of 152.4 mm (6 inches) and a thickness of 5 mm. Thus, sputtering targets were obtained.

After mounted on a sputtering apparatus (manufactured by Tokki Corporation, Ltd., SPF-530K), these sputtering targets were used for film deposition by the sputtering method under the same conditions as in Example 1. Then, the states of the targets were observed. As a result, in all of the targets, no cracks were formed, and no abnormal discharge or the like occurred within 10 minutes from the initial stage of the film deposition, either.

Next, the transmittance and the specific resistance value of the obtained film itself were measured and calculated in the same method as in Example 1. As a result, the transmittance in the visible region was 90% (Example 6), 90% (Example 7), 88% (Example 8), 88% (Example 9), 89% (Example 10), 89% (Example 11), 88% (Example 12), 83% (Example 7-2), 81% (Example 9-2), and 82% (Example 12-2), and the transmittance in the near-infrared region was 91% (Example 6), 91% (Example 7), 91% (Example 8), 91% (Example 9), 90% (Example 10), 91% (Example 11), 92% (Example 12), 82% (Example 7-2), 80% (Example 9-2), and 80% (Example 12-2).

Moreover, the specific resistance value was 8.0×10⁻⁴ Ω·cm (Example 6), 5.7×10⁻⁴ Ω·cm (Example 7), 8.2×10⁻⁴ Ω·cm (Example 8), 5.0×10⁻⁴ Ω·cm (Example 9), 7.1×10⁻⁴ Ω·cm (Example 10), 7.5×10⁻⁴ Ω·cm (Example 11), 5.4×10⁻⁴ Ω·cm (Example 12), 7.8×10⁻⁴ Ω·cm (Example 7-2), 6.1×10⁻⁴ Ω·cm (Example 9-2), and 7.2×10⁻⁴ Ω·cm (Example 12-2).

Accordingly, it has been found that the transparent conductive films of Examples 6 to 12, 7-2, 9-2, and 12-2 are excellent in transmittance not only in the visible region but also in the near-infrared region, and are useful not only for application to devices such as displays, which require visible light transmission, but also for application to solar cells, which require a high transmittance in the near-infrared region.

### Comparative Example 5

An oxide sintered body was obtained under the same conditions as in Example 1, except that the grinding was performed in a wet method using a ball mill apparatus into which hard ZrO₂ balls having a particle diameter of 3.0 mm were introduced, until the average particle diameter of the raw material powders became 0.5 μm or less.

The obtained oxide sintered body was subjected to powder X-ray diffraction measurement in the same method as in Example 1. As a result, only a peak of a ZnO phase having a hexagonal wurtzite structure was detected, and peaks originating from a SiO₂ phase as a single phase and a spinel-type composite oxide phase of zinc silicate (Zn₂SiO₄) were not detected.

End parts of the obtained oxide sintered body were cut into thin pieces by FIB processing, which were subsequently observed with a transmission electron microscope (TEM) equipped with an energy dispersive X-ray fluorescence spectrometer (EDX). As a result, the oxide sintered body, however, had a SiO₂ phase not contained in the matrix phase of the wurtzite-type structure into a solid solution phase possibly because aggregates were formed by the insufficient grinding and mixing of the raw material powders. Moreover, since it took 24 hours for the ball mill to grind the powders to 0.5 μm or less, the productivity significantly was low. Furthermore, a Zr component was detected at 4000 ppm, which was wore and mixed from the balls during the grinding. Hence, this production method cannot be used as the process of depositing films in large quantities, which require high productivity and quality.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 10 times to 20 times within 10 minutes from the initial stage of the film deposition. Such an oxide sintered body cannot be used in the process of depositing films in large quantities, which requires high productivity.

Next, the transmittance and the specific resistance value of the obtained film itself were measured and calculated in the same method as in Example 1. As a result, the transmittance was 82% in the visible region and 83% in the near-infrared region, and the specific resistance value was 9.8×10⁻⁴ Ω·cm.

### Comparative Example 6

An oxide sintered body was obtained under the same conditions as in Example 1, except that a ZnO powder having an average particle diameter of 1.3 μm and a SiO₂ powder having an average particle diameter of 1.5 μm were used as raw material powders.

The obtained oxide sintered body was subjected to powder X-ray diffraction measurement in the same method as in Example 1. As a result, only a peak of a ZnO phase having a hexagonal wurtzite structure was detected, and peaks originating from a SiO₂ phase as a single phase and a spinel-type composite oxide phase of zinc silicate (Zn₂SiO₄) were not detected.

End parts of the obtained oxide sintered body were cut into thin pieces by FIB processing, which were subsequently observed with a transmission electron microscope (TEM) equipped with an energy dispersive X-ray fluorescence spectrometer (EDX). As a result, the oxide sintered body, however, had the raw material powders with a large particle diameter, Si uniformly dispersed only in a macroscopic scale was not contained in the matrix phase of the wurtzite-type structure into a solid solution phase, and a SiO₂ phase was present.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 20 times to 30 times within 10 minutes from the initial stage of the film deposition. Such an oxide sintered body cannot be used in the process of depositing films in large quantities, which requires high productivity.

Next, the transmittance and the specific resistance value of the obtained film itself were measured and calculated in the same method as in Example 1. As a result, the transmittance was 85% in the visible region and 85% in the near-infrared region, and the specific resistance value was 1.2×10⁻³ Ω·cm.

### Example 13

As raw material powders, a ZnO powder and a SiO₂ powder each having an average particle diameter of 1.0 μm or less were weighed with the atomic ratio of Si/(Zn+Si) being 3.0 atomic %.

Next, a slurry having a concentration of the raw material powders of 60 wt % was prepared in a mixing tank by mixing 60 wt % of the ZnO powder and 60 wt % of the SiO₂ powder with pure water and an organic dispersing agent.

The obtained slurry was spray dried by using a spray dryer apparatus (manufactured by OHKAWARA KAKOHKI CO., LTD., Model: ODL-20) to obtain a mixture powder having a particle diameter of 300 μm or less.

The mixture powder obtained were calcined for 20 hours in an atmospheric-pressure calcining furnace with the highest sintering temperature of 1200° C. After the calcining, the calcined mixture powder was ground to obtain a calcined powder of 300 μm or less. In this event, the rate of temperature rise was of 5° C./minute in a temperature range from 700 to 900° C., and 3° C./minute in a temperature range other than 700 to 900° C.

Next, a slurry having a concentration of the raw material powders of 70 wt % was prepared in a mixing tank by blending the obtained calcined powder with the remaining parts of the weighed ZnO and SiO₂ powders, pure water, an organic binder, and a dispersing agent. The slurry was spray dried by using the spray dryer apparatus to obtain a granulated powder having a particle diameter of 300 μm.

Then, the obtained granulated powder was pressed in a die (with a wave press manufactured by Sansho Industry Co., Ltd.) to obtain 200 circular cylinder-shaped compacts each having a diameter of 30 mm and a height of 40 mm.

A compact obtained was sintered for 20 hours in an atmospheric-pressure sintering furnace with the highest sintering temperature of 1000° C. Thus, an oxide sintered body was obtained. In this event, the rate of temperature rise was of 5° C./minute in a temperature range from 700 to 900° C., and 3° C./minute in a temperature range other than 700 to 900° C.

The obtained oxide sintered bodies were subjected to powder X-ray diffraction measurement in the same method as in Example 1. As a result, only a peak of a ZnO phase having a hexagonal wurtzite structure was detected in all the 200 sintered bodies, and peaks originating from a SiO₂ phase as a single phase and a spinel-type composite oxide phase of zinc silicate (Zn₂SiO₄) were not detected.

Further, end parts of the obtained oxide sintered bodies were cut into thin pieces by FIB processing, which were subsequently observed with a transmission electron microscope (TEM) equipped with an energy dispersive X-ray fluorescence spectrometer (EDX). As a result, the electron diffraction also confirmed that the obtained oxide sintered bodies had no SiO₂ phase present as a single phase in the matrix phase of the wurtzite-type structure.

Next, a film was deposited by an ion plating method using each of the obtained sintered bodies as a tablet for vapor deposition. In the film deposition, a reactive plasma vapor deposition apparatus capable of high-density plasma-assist evaporation (HDPE method) was used. As the specific conditions, the distance between the evaporation source and a substrate was 0.6 m, the discharge current of a plasma gun was 100 A, the Ar flow rate was 30 sccm, and the O₂ flow rate was 10 sccm. While the tablet for vapor deposition was being continuously supplied into the vacuum vapor deposition apparatus, a film was deposited without heating. Thus, a transparent conductive film having a thickness of 200 nm was deposited. As a result, all the tablets for vapor deposition enabled stable film deposition. Neither chipping nor crack formation occurred during automatic transfer, and stable film deposition was possible.

Moreover, the transmittance and the specific resistance value of the obtained film itself were measured and calculated in the same method as in Example 1. As a result, the transmittance was 90% in the visible region and 92% in the near-infrared region, and the specific resistance value was 7.9×10⁻⁴ Ω·cm.

### Examples 14, 15, and Comparative Examples 7, 8

Oxide sintered bodies were obtained under the same conditions as in Example 13, except that the sintering temperature was 1400° C. (Example 14), 900° C. (Example 15), 1500° C. (Comparative Example 7), and 700° C. (Comparative Example 8).

The obtained oxide sintered bodies were subjected to powder X-ray diffraction measurement in the same method as in Example 1. As a result, only a peak of a ZnO phase having a hexagonal wurtzite structure was detected in all the sintered bodies, and peaks originating from a SiO₂ phase as a single phase and a spinel-type composite oxide phase of zinc silicate (Zn₂SiO₄) were not detected.

Further, end parts of the obtained oxide sintered bodies were cut into thin pieces by FIB processing, which were subsequently observed with a transmission electron microscope (TEM) equipped with an energy dispersive X-ray fluorescence spectrometer (EDX). As a result, the electron diffraction also confirmed that the oxide sintered bodies obtained in Examples 14, 15 and Comparative Example 8 had no SiO₂ phase present as a single phase in the matrix phase of the wurtzite-type structure. However, in Comparative Example 7, a region having a high Si concentration was formed inside the crystal particles adjacent to grain boundaries and a SiO₂ phase was present possibly because the sintering temperature was too high.

Vapor deposition was conducted by using each of the obtained sintered bodies as a tablet for vapor deposition, and irradiating the tablet with electron beams, while the tablet was being continuously supplied into a vacuum vapor deposition apparatus. As a result, stable film deposition was possible with the tablets for vapor deposition of Examples 14 and 15. However, in Comparative Example 7, the tablet was fractured and abnormal discharge and a splash phenomenon occurred during the film deposition because of insufficient resistance to thermal shock attributable to the electrically charged SiO₂ phase and the excessive sintering. Additionally, in the sintered body of Comparative Example 8, fractures were formed during the automatic transfer and during the film deposition due to the insufficient sintering. These oxide sintered bodies of Comparative Examples 7 and 8 cannot be used in the process of depositing films in large quantities, which requires high productivity.

Next, the transmittance and the specific resistance value of the obtained film itself were measured and calculated in the same method as in Example 1. As a result, the transmittance in the visible region was 90% (Example 14), 90% (Example 15), 86% (Comparative Example 7), and 88% (Comparative Example 8), and the transmittance in the near-infrared region was 93% (Example 14), 91% (Example 15), 88% (Comparative Example 7), and 89% (Comparative Example 8).

Moreover, the specific resistance value was 8.2×10⁻⁴ Ω·cm (Example 14), 8.0×10⁻⁴ Ω·cm (Example 15), 8.9×10⁻⁴ Ω·cm (Comparative Example 7), and 8.7×10⁻⁴ Ω·cm (Comparative Example 8).

It is thought that the transmittance of the transparent conductive films obtained in Comparative Examples 7 and 8 was adversely influenced by the unstable film deposition. It has been found that such transparent conductive films cannot be used as a transparent electrode film, which requires a high transmittance.

### Comparative Example 9

As raw material powders, a ZnO powder and a SiO₂ powder each having an average particle diameter of 0.4 μm were blended with each other with the atomic ratio of Si/(Zn+Si) being 4.0 atomic %. The resultant was ground in a dry method using a ball mill apparatus into which hard ZrO₂ balls having a particle diameter of 3.0 mm were introduced, until the average particle diameter of the raw material powders became 0.3 μm or less. Thus, a granulated powder was obtained.

Next, the obtained granulated powder was sintered under conditions of 15 MPa (150 kg/cm²) and 1000° C. with a vacuum hot press. Thus, an oxide sintered body was obtained. In this event, the rate of temperature rise was all 3° C./minute.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, Si uniformly dispersed only in a macroscopic scale was not contained in the matrix phase of the wurtzite-type structure into a solid solution phase and the oxide sintered body had a SiO₂ phase possibly because aggregates were formed by the insufficient grinding and mixing of the raw material powders.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 10 times to 20 times within 10 minutes from the initial stage of the film deposition. Such an oxide sintered body cannot be used in the process of depositing films in large quantities, which requires high productivity.

Next, the transmittance and the specific resistance value of the obtained film itself were measured and calculated in the same method as in Example 1. As a result, the transmittance was 82% in the visible region and 79% in the near-infrared region, and the specific resistance value was 7.0×10⁻⁴ Ω·cm.

### Comparative Example 10

As raw material powders, a ZnO powder, a SiO₂ powder, and an Al₂O₃ powder each having an average particle diameter of 0.1 μm were blended with each other with the atomic ratio of Si/(Zn+Si) being 1.1 atomic % and the atomic ratio of Al/(Zn+Si+Al) being 3.5 atomic %, and mixed with pure water, an organic binder, and a dispersing agent. The mixing was performed with a concentration of the raw material powders being 60 wt %, and a slurry was prepared in a mixing tank.

Next, a granulated powder was obtained under the same conditions as in Example 1, except that the slurry was ground in a wet method for 18 hours using a ball mill apparatus into which hard ZrO₂ balls having a particle diameter of 3.0 mm were introduced.

The obtained granulated powder was pressed by applying a pressure of 294 MPa (3 ton/cm²) thereto with a cold isostatic press. A compact of approximately 200 mmφ thus obtained was sintered for 5 hours in an atmospheric-pressure sintering furnace with the highest sintering temperature of 1300° C. Thus, an oxide sintered body was obtained. In this event, the rate of temperature rise was 1° C./minute from room temperature to 800° C., and 3° C./minute from 800 to 1300° C.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, Si uniformly dispersed only in a macroscopic scale was not contained in the matrix phase of the wurtzite-type structure into a solid solution phase and the oxide sintered body had a SiO₂ phase possibly because aggregates were formed by the insufficient grinding and mixing of the raw material powders.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 3 times within 10 minutes from the initial stage of the film deposition. Such an oxide sintered body suppresses abnormal discharge, but cannot completely eliminate abnormal discharge and cannot be used in the process of depositing films in large quantities, which requires high productivity because the yield is likely to deteriorate.

Moreover, the transmittance and the specific resistance value of the obtained film itself were measured and calculated in the same method as in Example 1. As a result, the transmittance was 82% in the visible region and 75% in the near-infrared region, and the specific resistance value was 8.0×10⁻⁴ Ω·cm.

### Comparative Example 11

As raw material powders, a ZnO powder, a SiO₂ powder, and a Ga₂O₃ powder each having an average particle diameter of 0.1 μm were blended with each other with the atomic ratio of Si/(Zn+Si) being 0.85 atomic % and the atomic ratio Ga/(Zn+Si+Ga) being 4.0 atomic %, and mixed with pure water, an organic binder, and a dispersing agent. The mixing was performed with a concentration of the raw material powders being 60 wt %, and a slurry was prepared in a mixing tank.

Next, a granulated powder was obtained under the same conditions as in Example 1, except that the slurry was ground in a wet method for 18 hours using a ball mill apparatus into which hard ZrO₂ balls having a particle diameter of 3.0 mm were introduced.

Next, the obtained granulated powder was pressed by applying a pressure of 294 MPa (3 ton/cm²) thereto with a cold isostatic press. A compact of approximately 200 mmφ thus obtained was sintered for 5 hours in air in an atmospheric-pressure sintering furnace with the highest sintering temperature of 1300° C. Thus, an oxide sintered body was obtained. In this event, the rate of temperature rise was 1° C./minute from room temperature to 800° C., and 3° C./minute from 800 to 1300° C.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, Si uniformly dispersed only in a macroscopic scale was not contained in the matrix phase of the wurtzite-type structure into a solid solution phase and the oxide sintered body had a SiO₂ phase possibly because aggregates were formed by the insufficient grinding and mixing of the raw material powders.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 3 times within 10 minutes from the initial stage of the film deposition. Such an oxide sintered body suppresses abnormal discharge, but cannot completely eliminate abnormal discharge and cannot be used in the process of depositing films in large quantities, which requires high productivity because the yield is likely to deteriorate.

Moreover, the transmittance and the specific resistance value of the obtained film itself were measured and calculated in the same method as in Example 1. As a result, the transmittance was 82% in the visible region and 76% in the near-infrared region, and the specific resistance value was 7.5×10⁻⁴ Ω·cm.

### Comparative Example 12

As raw material powders, a ZnO powder, a SiO₂ powder, and an Al₂O₃ powder each having an average particle diameter of 0.1 μm were blended with each other with the atomic ratio of Si/(Zn+Si) being 0.7 atomic % and the atomic ratio of Al/(Zn+Si+Al) being 4.7 atomic %, and mixed with pure water, an organic binder, and a dispersing agent. The mixing was performed with a concentration of the raw material powders being 60 wt %, and a slurry was prepared in a mixing tank.

Next, a granulated powder was obtained under the same conditions as in Example 1, except that the slurry was ground in a wet method for 18 hours using a ball mill apparatus into which hard ZrO₂ balls having a particle diameter of 3.0 mm were introduced.

The obtained granulated powder was pressed by applying a pressure of 98 MPa (1 ton/cm²) thereto with a cold isostatic press. A compact of approximately 200 mmφ thus obtained was sintered for 5 hours in air in an atmospheric-pressure sintering furnace with the highest sintering temperature of 1500° C. Thus, an oxide sintered body was obtained. In this event, the rate of temperature rise was 1° C./minute from room temperature to 1000° C., and 3° C./minute from 1000 to 1500° C.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, a region having a high Si concentration was formed inside the crystal particles adjacent to grain boundaries and the oxide sintered body had a SiO₂ phase possibly because aggregates were formed by the insufficient grinding and mixing of the raw material powders, and because the sintering temperature was too high.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 3 times within 10 minutes from the initial stage of the film deposition. Such an oxide sintered body suppresses abnormal discharge, but cannot completely eliminate abnormal discharge and cannot be used in the process of depositing films in large quantities, which requires high productivity because the yield is likely to deteriorate. Moreover, the crystal particles were coarsened possibly because the sintering temperature of 1500° C. was too high under the target production conditions, and the strength of the sintered body was so low that 4 targets among 20 targets were fractured during the processing.

Moreover, the transmittance and the specific resistance value of the obtained film itself were measured and calculated in the same method as in Example 1. As a result, the transmittance was 85% in the visible region and 76% in the near-infrared region, and the specific resistance value was 5.0×10⁻⁴ Ω·cm.

### Comparative Example 13

As raw material powders, a ZnO powder, a SiO₂ powder, and an Al₂O₃ powder each having an average particle diameter of 1.0 μm or less were blended with each other with the atomic ratio of Si/(Zn+Si) being 6.8 atomic % and the atomic ratio of Al/(Zn+Si+Al) being 3.1 atomic %. The resultant was not ground but subjected to only dry mixing to obtain a mixture powder.

Next, a granulated powder was obtained under the same conditions as in Example 1, except that the resultant was ground in a wet method for 18 hours using a ball mill apparatus into which hard ZrO₂ balls having a particle diameter of 3.0 mm were introduced.

The obtained granulated powder was pressed by applying a pressure of 98 MPa (1 ton/cm²) thereto with a cold isostatic press. A compact of approximately 200 mmφ thus obtained was sintered for 20 hours in air in an atmospheric-pressure sintering furnace with the highest sintering temperature of 1400° C. Thus, an oxide sintered body was obtained. In this event, the rate of temperature rise was all 3° C./minute.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, Si uniformly dispersed only in a macroscopic scale was not contained in the matrix phase of the wurtzite-type structure into a solid solution phase and the oxide sintered body had a SiO₂ phase possibly because aggregates were formed by the insufficient grinding and mixing of the raw material powders.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 10 times to 20 times within 10 minutes from the initial stage of the film deposition. Such an oxide sintered body cannot be used in the process of depositing films in large quantities, which requires high productivity.

Moreover, the transmittance and the specific resistance value of the obtained film itself were measured and calculated in the same method as in Example 1. As a result, the transmittance was 79% in the visible region and 77% in the near-infrared region, and the specific resistance value was 4.3×10⁻³ Ω·cm.

### Comparative Example 14

As raw material powders, a ZnO powder and a SiO₂ powder each having an average particle diameter of 1.0 μm or less were blended with each other with the atomic ratio of Si/(Zn+Si) being 5.0 atomic %. These raw material powders were mixed for 20 hours using a ball mill apparatus into which hard ZrO₂ balls having a particle diameter of 3.0 mm were introduced, and then dried to obtain a mixture powder.

The mixture powder was calcined for 2 hours in air in an atmospheric-pressure calcining furnace at a rate of temperature rise of 3° C./minute with the highest calcining temperature of 1300° C. to obtain a calcined powder. The calcined powder was subjected to the ball mill processing in the same method as above. The calcined powder was blended with a ZnO powder, which was equivalent to the above ZnO powder with the atomic ratio of Si/(Zn+Si) being 3.0 atomic %, mixed for 20 hours using the ball mill and dried to obtain a mixture powder.

Next, polyvinyl alcohol was added to the obtained mixture powder to prepare a granulated powder. Then, the granulated powder was used and pressed by applying a pressure of 98 MPa (1 ton/cm²) thereto with a uniaxial pressing machine, and further pressed by applying a pressure of 294 MPa (3 ton/cm²) thereto with a cold isostatic pressing to obtain a compact of approximately 200 mmφ. After dewaxing in air at 600° C. for 1 hour, the obtained compact was sintered for 2 hours in air in an atmospheric-pressure sintering furnace with the highest sintering temperature of 1400° C. Thus, an oxide sintered body was obtained. In this event, the rate of temperature rise was all 3° C./minute.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, Si uniformly dispersed only in a macroscopic scale was not contained in the matrix phase of the wurtzite-type structure into a solid solution phase and the oxide sintered body had a SiO₂ phase possibly because aggregates were formed by the insufficient grinding and mixing of the raw material powders.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 20 times to 30 times within 10 minutes from the initial stage of the film deposition. Such an oxide sintered body cannot be used in the process of depositing films in large quantities, which requires high productivity.

Moreover, the transmittance and the specific resistance value of the obtained film itself were measured and calculated in the same method as in Example 1. As a result, the transmittance was 80% in the visible region and 78% in the near-infrared region, and the specific resistance value was 9.5×10⁻⁴ Ω·cm.

### Comparative Example 15

A ZnO powder, a SiO₂ powder, an Al₂O₃ powder, and a MgO powder each having an average particle diameter of 5.0 μm were weighed and prepared with the atomic ratio of Si/(Zn+Si) being 0.5 atomic % and the atomic ratio of (Al+Mg)/(Zn+Si+Al+Mg) being 5.1 atomic %.

Next, the ZnO powder and the Al₂O₃ powder were mixed and then calcined in an atmospheric-pressure calcining furnace at a rate of temperature rise of 3° C./minute with the highest temperature of 1000° C. Thus, calcined powder (1) that was an AZO powder was obtained.

On the other hand, the SiO₂ powder and the MgO powder were calcined at 1000° C. in the same method as in the AZO powder preparation. Thus, a calcined powder (2) was obtained.

Next, the calcined powders (1) and (2) were further mixed and calcined again. Then, the powders thus calcined again were ground and granulated using a ball mill apparatus into which hard ZrO₂ balls having a particle diameter of 3.0 mm were introduced, until the average particle diameter became 1.0 μm or less.

The obtained granulated powder was pressed by applying a pressure of 49 MPa (500 kg/cm²) thereto. A compact of approximately 200 mmφ thus obtained was sintered for 5 hours in an oxygen atmosphere in an atmospheric-pressure sintering furnace with the highest sintering temperature of 1400° C. Thus, an oxide sintered body was obtained. In this event, the rate of temperature rise was all 3° C./minute.

The obtained oxide sintered body was subjected to powder X-ray diffraction measurement in the same method as in Example 1. As a result, peaks originating from a ZnO phase having a hexagonal wurtzite structure and a spinel-type composite oxide phase of zinc silicate (Zn₂SiO₄) were detected.

Further, end parts of the obtained oxide sintered body were cut into thin pieces by FIB processing, which were subsequently observed with a transmission electron microscope (TEM) equipped with an energy dispersive X-ray fluorescence spectrometer (EDX). As a result, the oxide sintered body had the raw material powders with a large particle diameter, Si uniformly dispersed only in a macroscopic scale was not contained in the matrix phase of the wurtzite-type structure into a solid solution phase, and a SiO₂ phase was present.

Next, the obtained oxide sintered body was processed into a diameter of 152.4 mm (6 inches) and a thickness of 5 mm. Thus, a sputtering target was obtained.

After mounted on a sputtering apparatus (manufactured by Tokki Corporation, Ltd., SPF-530K), the sputtering target was used for film deposition by the sputtering method under the same conditions as in Example 1. Then, the state of the target was observed. As a result, abnormal discharge occurred 20 times to 30 times within 10 minutes from the initial stage of the film deposition. Such an oxide sintered body cannot be used in the process of depositing films in large quantities, which requires high productivity.

Moreover, the transmittance and the specific resistance value of the obtained film itself were measured and calculated in the same method as in Example 1. As a result, the transmittance was 88% in the visible region and 89% in the near-infrared region, and the specific resistance value was 9.0×10⁻⁴ Ω·cm.

TABLE 1-1

| | Application | | Third component M |
|---|---|---|---|
| | of sintered | Si/(Zn + Si) | M/(Zn + Si + M) |
| Example: | body | (%) | (%) |
| 1 | Target | 3.0 | — |
| 2 | | 3.0 | — |
| 3 | | 3.0 | — |
| 4 | | 0.1 | — |
| 5 | | 10 | — |
| 6 | | 3.0 | Mg (2.0) |
| 7 | | 3.0 | Al (2.0) |
| 7-2 | | 3.0 | Al (10.0) |
| 8 | | 3.0 | Ti (2.0) |
| 9 | | 3.0 | Ga (2.0) |
| 9-2 | | 3.0 | Ga (10.0) |
| 10 | | 3.0 | In (2.0) |
| 11 | | 3.0 | Sn (2.0) |
| 12 | | 3.0 | Al + Ga (2.0) |
| 12-2 | | 3.0 | Al + Ga (10.0) |
| 13 | Tablet | 3.0 | — |
| 14 | | 3.0 | — |
| 15 | | 3.0 | — |

TABLE 1-2

| | Sintered body production | | | |
|---|---|---|---|---|
| | Particle | Particle | Raw | |
| | diameter of | diameter of | material | |
| | ZnO raw | SiO₂ raw | powder | Sintering |
| | material | material | grinding | temperature |
| Example: | powder (μm) | powder (μm) | apparatus | (° C.) |
| 1 | <1.0 | <1.0 | Bead mill | 1300 |
| 2 | <1.0 | <1.0 | Bead mill | 1400 |
| 3 | <1.0 | <1.0 | Bead mill | 900 |
| 4 | <1.0 | <1.0 | Bead mill | 1300 |
| 5 | <1.0 | <1.0 | Bead mill | 1300 |
| 6 | <1.0 | <1.0 | Bead mill | 1300 |
| 7 | <1.0 | <1.0 | Bead mill | 1300 |
| 7-2 | <1.0 | <1.0 | Bead mill | 1300 |
| 8 | <1.0 | <1.0 | Bead mill | 1300 |
| 9 | <1.0 | <1.0 | Bead mill | 1300 |
| 9-2 | <1.0 | <1.0 | Bead mill | 1300 |
| 10 | <1.0 | <1.0 | Bead mill | 1300 |
| 11 | <1.0 | <1.0 | Bead mill | 1300 |
| 12 | <1.0 | <1.0 | Bead mill | 1300 |
| 12-2 | <1.0 | <1.0 | Bead mill | 1300 |
| 13 | <1.0 | <1.0 | Bead mill | 1000 |
| 14 | <1.0 | <1.0 | Bead mill | 1400 |
| 15 | <1.0 | <1.0 | Bead mill | 900 |

TABLE 1-3

| | Sintered body production | |
|---|---|---|
| | | Fracture forma- |
| | | tion during |
| Example: | Rate of temperature rise | production step |
| 1 | 5° C./min. (700 to 900° C.) | Absent |
| | 3° C./min. (other than 700 to 900° C.) | |
| 2 | 5° C./min. (700 to 900° C.) | Absent |
| | 3° C./min. (other than 700 to 900° C.) | |
| 3 | 5° C./min. (700 to 900° C.) | Absent |
| | 3° C./min. (other than 700 to 900° C.) | |
| 4 | 5° C./min. (700 to 900° C.) | Absent |
| | 3° C./min. (other than 700 to 900° C.) | |
| 5 | 5° C./min. (700 to 900° C.) | Absent |
| | 3° C./min. (other than 700 to 900° C.) | |
| 6 | 5° C./min. (700 to 900° C.) | Absent |
| | 3° C./min. (other than 700 to 900° C.) | |
| 7 | 5° C./min. (700 to 900° C.) | Absent |
| | 3° C./min. (other than 700 to 900° C.) | |
| 7-2 | 5° C./min. (700 to 900° C.) | Absent |
| | 3° C./min. (other than 700 to 900° C.) | |
| 8 | 5° C./min. (700 to 900° C.) | Absent |
| | 3° C./min. (other than 700 to 900° C.) | |
| 9 | 5° C./min. (700 to 900° C.) | Absent |
| | 3° C./min. (other than 700 to 900° C.) | |
| 9-2 | 5° C./min. (700 to 900° C.) | Absent |
| | 3° C./min. (other than 700 to 900° C.) | |
| 10 | 5° C./min. (700 to 900° C.) | Absent |
| | 3° C./min. (other than 700 to 900° C.) | |
| 11 | 5° C./min. (700 to 900° C.) | Absent |
| | 3° C./min. (other than 700 to 900° C.) | |
| 12 | 5° C./min. (700 to 900° C.) | Absent |
| | 3° C./min. (other than 700 to 900° C.) | |
| 12-2 | 5° C./min. (700 to 900° C.) | Absent |
| | 3° C./min. (other than 700 to 900° C.) | |
| 13 | 5° C./min. (700 to 900° C.) | Absent |
| | 3° C./min. (other than 700 to 900° C.) | |
| 14 | 5° C./min. (700 to 900° C.) | Absent |
| | 3° C./min. (other than 700 to 900° C.) | |
| 15 | 5° C./min. (700 to 900° C.) | Absent |
| | 3° C./min. (other than 700 to 900° C.) | |

TABLE 2-1

| | Sintered body | | Deposited film | |
|---|---|---|---|---|
| | | Intermediate | Abnormal discharge | Crack |
| Exam- | SiO₂ | compound phase | etc. during | during film |
| ple: | phase | such as spinel | film deposition | deposition |
| 1 | Absent | Absent | Absent | Absent |
| 2 | Absent | Absent | Absent | Absent |
| 3 | Absent | Absent | Absent | Absent |
| 4 | Absent | Absent | Absent | Absent |
| 5 | Absent | Absent | Absent | Absent |
| 6 | Absent | Absent | Absent | Absent |
| 7 | Absent | Absent | Absent | Absent |
| 7-2 | Absent | Absent | Absent | Absent |
| 8 | Absent | Absent | Absent | Absent |
| 9 | Absent | Absent | Absent | Absent |
| 9-2 | Absent | Absent | Absent | Absent |
| 10 | Absent | Absent | Absent | Absent |
| 11 | Absent | Absent | Absent | Absent |
| 12 | Absent | Absent | Absent | Absent |
| 12-2 | Absent | Absent | Absent | Absent |
| 13 | Absent | Absent | Absent | Absent |
| 14 | Absent | Absent | Absent | Absent |
| 15 | Absent | Absent | Absent | Absent |

TABLE 2-2

| | Transparent conductive film | | |
|---|---|---|---|
| | Transmittance | Transmittance in | |
| | in visible | near-infrared | Specific |
| | region (%) | region (%) | resistance |
| Example: | *1 | *2 | (Ω · cm) |
| 1 | 89 | 92 | 8.5 × 10⁻⁴ |
| 2 | 89 | 93 | 8.6 × 10⁻⁴ |
| 3 | 88 | 92 | 9.0 × 10⁻⁴ |
| 4 | 88 | 94 | 9.0 × 10⁻⁴ |
| 5 | 90 | 89 | 8.1 × 10⁻⁴ |
| 6 | 90 | 91 | 8.0 × 10⁻⁴ |
| 7 | 90 | 91 | 5.7 × 10⁻⁴ |
| 7-2 | 83 | 82 | 7.8 × 10⁻⁴ |
| 8 | 88 | 91 | 8.2 × 10⁻⁴ |
| 9 | 88 | 91 | 5.0 × 10⁻⁴ |
| 9-2 | 81 | 80 | 6.1 × 10⁻⁴ |
| 10 | 89 | 90 | 7.1 × 10⁻⁴ |
| 11 | 89 | 91 | 7.5 × 10⁻⁴ |
| 12 | 88 | 92 | 5.4 × 10⁻⁴ |
| 12-2 | 82 | 80 | 7.2 × 10⁻⁴ |
| 13 | 90 | 92 | 7.9 × 10⁻⁴ |
| 14 | 90 | 93 | 8.2 × 10⁻⁴ |
| 15 | 90 | 91 | 8.0 × 10⁻⁴ |

*1 The wavelength in the visible region is 400 nm to 800 nm.
*2 The wavelength in the near-infrared region is 800 nm to 1200 nm.

TABLE 3-1

| | Application | | Third component M |
|---|---|---|---|
| Comparative | of sintered | Si/(Zn + Si) | M/(Zn + Si + M) |
| Example: | body | (%) | (%) |
| 1 | Target | 3.0 | — |
| 2 | | 3.0 | — |
| 3 | | 0 | — |
| 4 | | 15 | — |
| 5 | | 3.0 | — |
| 6 | | 3.0 | — |
| 7 | Tablet | 3.0 | — |
| 8 | | 3.0 | — |
| 9 | Target | 4.0 | — |
| 10 | | 1.1 | Al (3.5) |
| 11 | | 0.85 | Ga (4.0) |
| 12 | | 0.7 | Al (4.7) |
| 13 | | 6.8 | Al (3.1) |
| 14 | | 3.0 | — |
| 15 | | 0.5 | Al + Mg (5.1) |

TABLE 3-2

| | Sintered body production | | |
|---|---|---|---|
| | Particle diameter | Particle diameter | Raw material |
| | of ZnO raw | of SiO₂ raw | powder |
| Comparative | material | material | grinding |
| Example: | powder (μm) | powder (μm) | apparatus |
| 1 | <1.0 | <1.0 | Bead mill |
| 2 | <1.0 | <1.0 | Bead mill |
| 3 | <1.0 | <1.0 | Bead mill |
| 4 | <1.0 | <1.0 | Bead mill |
| 5 | <1.0 | <1.0 | Ball mill |
| 6 | 1.3 | 1.5 | Bead mill |
| 7 | <1.0 | <1.0 | Bead mill |
| 8 | <1.0 | <1.0 | Bead mill |
| 9 | 0.4 | 0.4 | Ball mill |
| 10 | <1.0 | <1.0 | Ball mill |
| 11 | <1.0 | <1.0 | Ball mill |
| 12 | <1.0 | <1.0 | Ball mill |
| 13 | <1.0 | <1.0 | Ball mill |
| 14 | <1.0 | <1.0 | Ball mill |
| 15 | 5.0 | 5.0 | Ball mill |

TABLE 3-3

| | Sintered body production | | |
|---|---|---|---|
| | | | Fracture |
| Compar- | Sintering | | formation |
| ative | temperature | | during pro- |
| Example: | (° C.) | Rate of temperature rise | duction step |
| 1 | 1500 | 5° C./min. (700 to 900° C.) | Present |
| | | 3° C./min. (other than 700 to | |
| | | 900° C.) | |
| 2 | 800 | 5° C./min. (700 to 900° C.) | Present |
| | | 3° C./niin. (other than 700 to | |
| | | 900° C.) | |
| 3 | 1300 | 5° C./min. (700 to 900° C.) | Absent |
| | | 3° C./min. (other than 700 to | |
| | | 900° C.) | |
| 4 | 1300 | 5° C./min. (700 to 900° C.) | Absent |
| | | 3° C./min. (other than 700 to | |
| | | 900° C.) | |
| 5 | 1300 | 5° C./min. (700 to 900° C.) | Absent |
| | | 3° C./min. (other than 700 to | |
| | | 900° C.) | |
| 6 | 1300 | 5° C./min. (700 to 900° C.) | Absent |
| | | 3° C./min. (other than 700 to | |
| | | 900° C.) | |
| 7 | 1500 | 5° C./min. (700 to 900° C.) | Present |
| | | 3° C./min. (other than 700 to | |
| | | 900° C.) | |
| 8 | 700 | 5° C./min. (700 to 900° C.) | Present |
| | | 3° C./min. (other than 700 to | |
| | | 900° C.) | |
| 9 | 1000 | All 3° C./min. | Absent |
| 10 | 1300 | 1° C./min. (room temperature to | Absent |
| | | 800° C.) | |
| | | 3° C./min. (800 to 1300° C.) | |
| 11 | 1300 | 1° C./min. (room temperature to | Absent |
| | | 800° C.) | |
| | | 3° C./min. (800 to 1300° C.) | |
| 12 | 1500 | 1° C./min. (room temperature to | Present |
| | | 1000° C.) | |
| | | 3° C./min. (1000 to 1500° C.) | |
| 13 | 1400 | All 3° C./min. | Absent |
| 14 | 1400 | All 3° C./min. | Present |
| 15 | 1400 | All 3° C./min. | Present |

TABLE 4-1

| | Sintered body | | Deposited film | |
|---|---|---|---|---|
| | | Intermediate | Abnormal | Crack |
| | | compound | discharge etc. | during |
| Comparative | SiO₂ | phase such | during film | film |
| Example: | phase | as spinel | deposition | deposition |
| 1 | Present | Absent | Present | Present |
| 2 | Absent | Absent | Present | Present |
| 3 | Absent | Absent | Present | Present |
| 4 | Present | Present | Present | Present |
| 5 | Present | Absent | Present | Present |
| 6 | Present | Absent | Present | Present |
| 7 | Present | Absent | Present | Present |
| 8 | Absent | Absent | Present | Present |
| 9 | Present | Present | Present | Present |
| 10 | Present | Present | Present | Present |
| 11 | Present | Present | Present | Present |
| 12 | Present | Present | Present | Present |
| 13 | Present | Present | Present | Present |
| 14 | Present | Present | Present | Present |
| 15 | Present | Present | Present | Present |

TABLE 4-2

Transparent conductive film

| | Transmittance | Transmittance in | |
|---|---|---|---|
| | in visible | near-infrared | Specific |
| Comparative | region (%) | region (%) | resistance |
| Example: | *1 | *2 | (Ω · cm) |
| 1 | 77 | 79 | 8.5 × 10⁻⁴ |
| 2 | 81 | 81 | 8.8 × 10⁻⁴ |
| 3 | 89 | 90 | 7.8 × 10⁻² |
| 4 | 78 | 76 | 8.2 × 10⁻⁴ |
| 5 | 82 | 83 | 9.8 × 10⁻⁴ |
| 6 | 85 | 85 | 1.2 × 10⁻³ |
| 7 | 86 | 88 | 8.9 × 10⁻⁴ |
| 8 | 88 | 89 | 8.7 × 10⁻⁴ |
| 9 | 82 | 79 | 7.0 × 10⁻⁴ |
| 10 | 82 | 75 | 8.0 × 10⁻⁴ |
| 11 | 82 | 76 | 7.5 × 10⁻⁴ |
| 12 | 85 | 76 | 5.0 × 10⁻⁴ |
| 13 | 79 | 77 | 4.3 × 10⁻³ |
| 14 | 80 | 78 | 9.5 × 10⁻⁴ |
| 15 | 88 | 89 | 9.0 × 10⁻⁴ |

*1 The wavelength in the visible region is 400 nm to 800 nm.
*2 The wavelength in the near-infrared region is 800 nm to 1200 nm.

### POSSIBILITY OF INDUSTRIAL APPLICATION

The Zn—Si—O-based oxide sintered body of the present invention suppresses abnormal discharge and so forth when used as a sputtering target, or suppresses a splash phenomenon when used as a tablet for vapor deposition. Accordingly, the Zn—Si—O-based oxide sintered body of the present invention has an industrial applicability of being used as a material for depositing transparent conductive films, which are used as electrodes for displays, touch panels, and solar cells, and so forth.

1. A Zn—Si—O-based oxide sintered body containing zinc oxide as a main component and Si, characterized in that
a Si content is 0.1 to 10 atomic % with an atomic ratio of Si/(Zn+Si),
the Si element is contained in a wurtzite-type zinc oxide phase to form a solid solution, and
the oxide sintered body does not contain a SiO₂ phase and zinc silicate (Zn₂SiO₄) as a spinel-type composite oxide phase.

2. The Zn—Si—O-based oxide sintered body according to claim 1, characterized in that at least one selected from the group consisting of Mg, Al, Ti, Ga, In, and Sn is added, and
the additional element is contained in the wurtzite-type zinc oxide phase to form a solid solution.

3. The oxide sintered body according to claim 2, characterized in that a content of all components of the additional elements is 0.01 to 10 atomic % with an atomic ratio of M/(Zn+Si+M), where M represents the all components of the additional elements.

4. A sputtering target characterized by being obtained by processing the Zn—Si—O-based oxide sintered body according to any one of claims 1 to 3.

5. A tablet for vapor deposition, characterized by being obtained from the Zn—Si—O-based oxide sintered body according to any one of claims 1 to 3.

6. A method for producing a Zn—Si—O-based oxide sintered body, which has a Si content of 0.1 to 10 atomic % with an atomic ratio of Si/(Zn+Si), the Si element being contained in a wurtzite-type zinc oxide phase to form a solid solution, and which does not contain a SiO₂ phase and zinc silicate (Zn₂SiO₄) as a spinel-type composite oxide phase, the method characterized by comprising:
a first step of drying a slurry obtained by mixing a ZnO powder and a SiO₂ powder with pure water, an organic binder, and a dispersing agent, followed by granulation;
a second step of pressing the obtained granulated powder to obtain a compact; and
a third step of sintering the obtained compact to obtain the sintered body, and
the third step to obtain the sintered body includes the steps of:
raising a temperature in a sintering furnace in a temperature range from 700 to 900° C. at a rate of temperature rise of 5° C./minute or more; and
sintering the compact from 900° C. to 1400° C. in the sintering furnace.

7. The method for producing a Zn—Si—O-based oxide sintered body according to claim 6, characterized in that, in the third step, the temperature is raised in a temperature range from 900° C. to a sintering temperature at a rate of temperature rise of 3° C./minute or less.

8. The method for producing a Zn—Si—O-based oxide sintered body according to claim 6, characterized in that, in the first step, the slurry is obtained by mixing the ZnO powder, the SiO₂ powder, and a calcined powder, which is obtained by mixing and calcining a ZnO powder and a SiO₂ powder, with the pure water, the organic binder, and the dispersing agent, with a total concentration of the ZnO powder, the SiO₂ powder, and the calcined powder, which are raw material powders, being 50 to 80 wt %, and by stirring for mixing for 10 hours or more.

9. The method for producing a Zn—Si—O-based oxide sintered body according to claim 8, characterized in that the calcined powder is obtained by mixing and calcining the ZnO powder and the SiO₂ powder under a condition of 900° C. to 1400° C.

10. The method for producing a Zn—Si—O-based oxide sintered body according to claim 6, characterized in that the ZnO powder and the SiO₂ powder used have an average particle diameter of 1.0 μm or less.

11. The method for producing a Zn—Si—O-based oxide sintered body according to claim 8, characterized in that the ZnO powder and the SiO₂ powder used have an average particle diameter of 1.0 μm or less.

12. The method for producing a Zn—Si—O-based oxide sintered body according to claim 9, characterized in that the ZnO powder and the SiO₂ powder used have an average particle diameter of 1.0 μm or less.

13. A transparent conductive film characterized by being deposited by a sputtering method using the sputtering target according to claim 4.

14. A transparent conductive film characterized by being deposited by a vapor deposition method using the tablet for vapor deposition according to claim 5.

15. The transparent conductive film according to claim 13, characterized in that
the film itself has a transmittance of 80% or more at a wavelength of 400 nm to 800 nm,
the film itself has a transmittance of 80% or more at a wavelength of 800 nm to 1200 nm, and
the film has a specific resistance of 9.0×10⁻⁴ Ω·cm or less.

16. The transparent conductive film according to claim 14, characterized in that
the film itself has a transmittance of 80% or more at a wavelength of 400 nm to 800 nm,
the film itself has a transmittance of 80% or more at a wavelength of 800 nm to 1200 nm, and
the film has a specific resistance of 9.0×10⁻⁴ Ω·cm or less.
